(19) United States
(12) Patent Application Publication
(10) Pub. No.: US 2001/0046126 A1
(43) Pub. Date: Nov. 29, 2001

(54) Flip-chip RF-ID tag

(76) Inventor: Gary M. Colello, N. Andover, MA (US)

Correspondence Address: Dike, Bronstein, Roberts & Cushman, Intellectual Property Practice Group, EDWARDS & ANGELL, LLP, 130 Water Street, Boston, MA, 02109, US

(21) Appl. No.: 09/785,790

(22) Filed: Feb. 16, 2001

Related U.S. Application Data
(60) Provisional application No. 60/183,470, filed on Feb. 18, 2000.

(51) Int. Cl. H05K 7/02; H05K 7/06; H05K 1/18

(52) U.S. Cl. 361/782; 361/761; 361/764; 361/760

(57) ABSTRACT

A non-contact smart card assembly and a method of manufacturing the same are disclosed. The non-contact smart card assembly includes a RF antenna for receiving and transmitting RF signals and an integrated circuit component for processing the RF signals. Both the RF antenna and the integrated circuit component are mounted to a substrate. The smart card assembly further includes a capacitor, which together with the RF antenna form a resonance circuit. The capacitor is electrically coupled to the RF antenna and the integrated circuit component using flip-chip bonding techniques, thereby increasing reliability of the smart card assembly. Further, because the smart card assembly can be manufactured by automated equipment, manufacturing costs are reduced.

### BACKGROUND OF THE INVENTION

1. Field of the Invention

This invention relates generally to a smart card assembly, and more particularly to a smart card assembly that conveys information without contact, wherein flip-chip bonding is used for interconnecting a surface-contact capacitor with both a radio frequency (RF) coil antenna and an integrated circuit component. The smart card assembly includes the integrated circuit component mounted to a base substrate, and a resonance circuit including the RF coil antenna and the surface-contact capacitor. Interconnections are made between the integrated circuit component, the surface-contact capacitor, and the RF coil antenna using the flip-chip bonding technique. Because this bonding technique allows interconnection by automated equipment, assembly costs are significantly reduced.

2. Background

A non-contact smart card assembly is a credit card-sized, microelectronic assembly that generally includes an integrated circuit component mounted to a base substrate and a resonance circuit, which includes a RF coil antenna mounted to the base substrate and a capacitor coupled in parallel with the RF coil antenna. The integrated circuit component generally includes a memory for storing information such as access privileges or security information, e.g., an identification (ID) number. Further, the RF coil antenna and the capacitor form the resonance circuit, which generally transmits and receives information between the smart card assembly and a smart card reader/writer via radio waves. In this way, a user can utilize the smart card assembly without having to make physical contact with a mechanical reader/writer head, thereby enhancing reliability and making the smart card assembly convenient and easy-to-use. The integrated circuit component and the resonance circuit of the noncontact smart card assembly have traditionally been interconnected using conventional bonding techniques such as wire bonding. However, the use of conventional wire bonding techniques for interconnecting microcircuits included in the integrated circuit component and the resonance circuit has drawbacks in that it is often difficult to control signal path lengths between the integrated circuit component and the resonance circuit. This is especially the case for components that have bonding pads located not only along a periphery of the component but also near the center of the component's face. Further, the use of conventional wire bonding techniques in manufacturing smart card assemblies has typically required some manual intervention by human assembly personnel, thereby resulting in more complicated manufacturing processes and higher manufacturing costs.

It would therefore be desirable to have a new microelectronic assembly that incorporates the functions of a non-contact smart card. Such a smart card assembly would not only be less expensive to manufacture but also have increased reliability. It would also be desirable to have a smart card assembly that can be manufactured by automated equipment.

### SUMMARY OF THE INVENTION

The present invention provides a non-contact smart card assembly that is less expensive to manufacture than conventional non-contact smart card assemblies. Further, because the non-contact smart card assembly of the present invention can be manufactured by automated equipment, reliability is increased over conventional non-contact smart card assemblies that are manufactured by manual processes.

In accordance with the present invention, a non-contact smart card assembly includes a substrate having a face side; a resonance circuit including a RF antenna formed on the face side of the substrate for transmitting or receiving RF signals, and a capacitor operatively coupled to the RF antenna; and, an integrated circuit component mounted to the face side of the substrate and operatively coupled to the capacitor of the resonance circuit, for processing the RF signals, wherein the capacitor is coupled to terminals of the RF antenna and bond pads of the integrated circuit component using only pressure contact between the components. In a preferred embodiment, the capacitor is a top-contact capacitor.

In another embodiment, the non-contact smart card assembly is manufactured by forming electrically conductive bumps on the bond pads of the integrated circuit component and the terminals of the RF antenna; aligning the electrodes of the capacitor with the bumps formed on the bond pads of the integrated circuit component and the terminals of the RF antenna; and, contacting the electrodes of the capacitor with the electrically conductive bumps.

In still another embodiment, the non-contact smart card assembly is manufactured by forming electrically conductive bumps on the electrodes of the capacitor; aligning the bond pads of the integrated circuit component and the terminals of the RF antenna with the bumps formed on the electrodes; and, contacting the bond pads and the terminals with the bumps formed on the electrodes.

According to one feature, the electrically conductive bumps are conductive polymer bumps.

Still further objects and advantages will become apparent from a consideration of the ensuing description and drawings.

### BRIEF DESCRIPTION OF THE DRAWINGS

The invention will be better understood by reference to the following more detailed description and accompanying drawings in which

FIG. 1 is an exploded view of a smart card assembly in accordance with the present invention;

FIG. 2 is a top plan view of a capacitor overlaying an integrated circuit component used with the smart card assembly shown in FIG. 1;

FIG. 3 is a side view of the smart card assembly shown in FIG. 1;

FIG. 4 is a bottom plan view of the capacitor shown in FIG. 2; and

FIG. 5 is a cross-sectional view of the capacitor shown in FIG. 4 taken along the line 5-5.

### DETAILED DESCRIPTION OF THE INVENTION

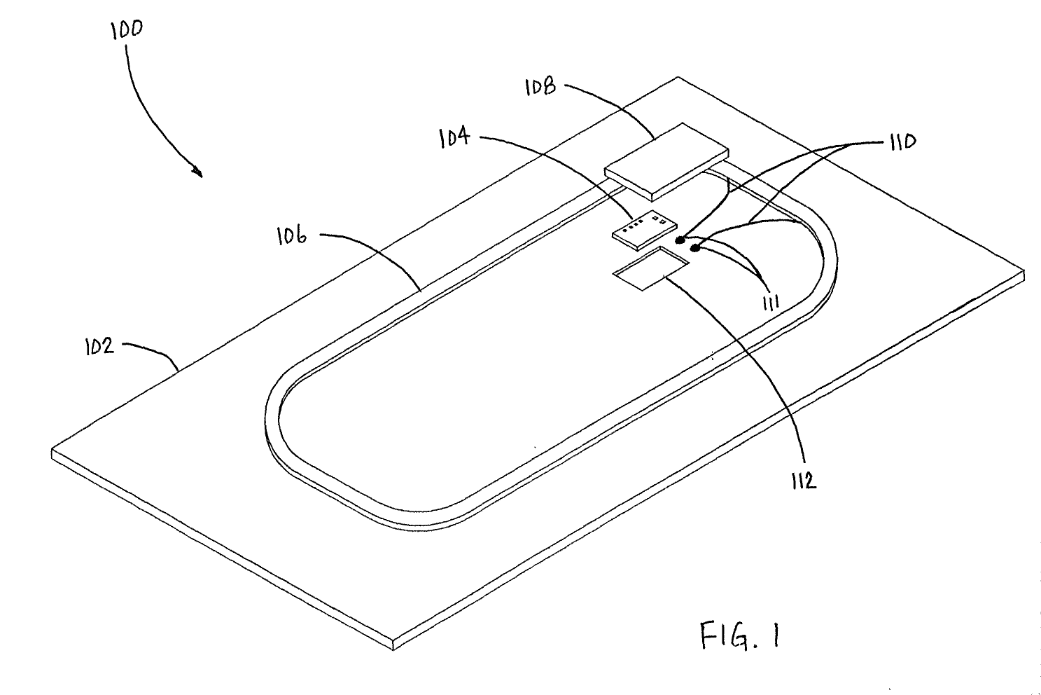

FIG. 1 shows an exploded view of a non-contact smart card assembly 100 in accordance a preferred embodiment of the present invention. The smart card assembly 100 includes a substantially planar substrate 102, an integrated circuit component 104, a RF coil antenna 106, and a capacitor 108. In this illustrative example, the substrate 102 may include a plurality of layers of suitable polymeric material (not shown), which are laminated together to form an integral component of a desired thickness. The substrate 102 may further include at least one protective outer layer also made of suitable polymeric material (not shown), which forms a protective coating overlaying the integrated circuit component 104, the RF coil antenna 106, and the capacitor 108. The overall dimensions of the substrate 102 including the protective outer layer are preferably comparable to those of a conventional credit card.

A component cavity 112 is preferably formed in the substrate 102. The component cavity 112 is sized and shaped to receive the integrated circuit component 104, which may be an application-specific integrated circuit. Further, the integrated circuit component 104 may be mounted to the substrate 102 within the component cavity 112 using a suitable adhesive.

The RF coil antenna 106 is formed on the surface of the substrate 102. For example, the RF coil antenna 106 can be formed by winding an insulated copper coil on the substantially planar surface of the substrate 102. Alternatively, the antenna 106 can be a conductive trace, a jumper trace, or any electrical element that can send or receive electrical signals. Further, conductive traces 110 are formed on the surface of the substrate 102 for providing electrical interconnections between the RF coil antenna 106 and the capacitor 108, which is disposed in an overlaying relationship with respect to the substrate 102 and the integrated circuit component 104 mounted within the component cavity 112. The interconnections between the capacitor 108, the integrated circuit component 104, and the conductive traces 110 will be described in detail later in this specification.

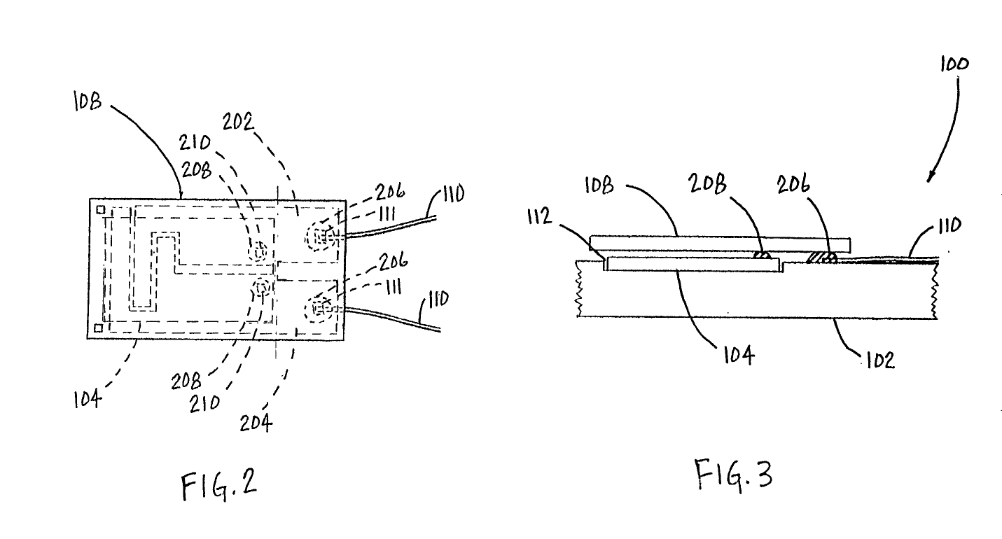

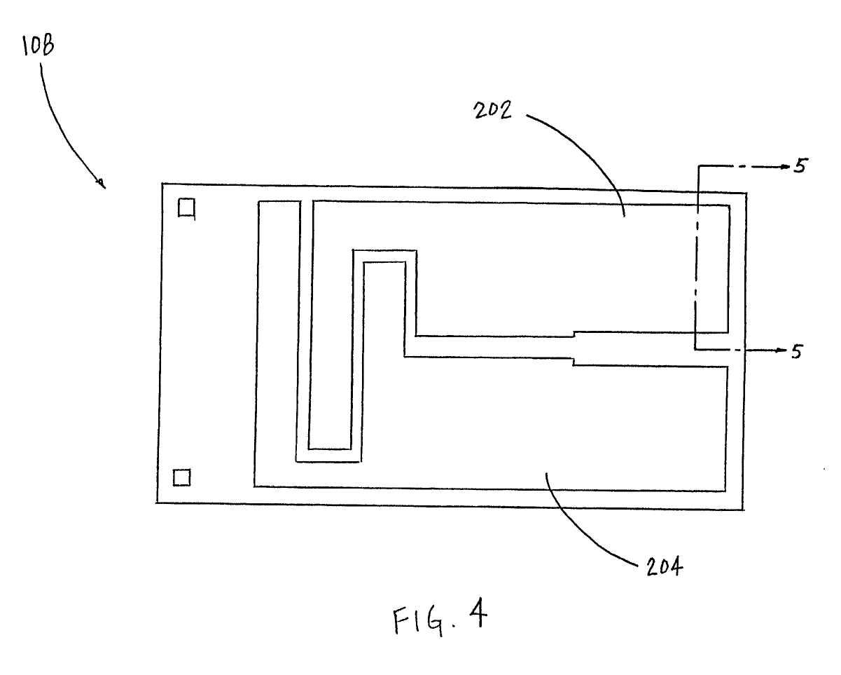

FIG. 2 shows a top plan view of the capacitor 108 disposed in the overlaying relationship with respect to the substrate 102 (see FIG. 1) and the integrated circuit component 104 (shown in shadow). Specifically, the capacitor 108 is a thin-film capacitor including metal layers 202 and 204 (see also FIG. 4) that form electrodes of the capacitor 108, thereby making the capacitor 108 a surface-contact capacitor or particularly a top-contact capacitor.

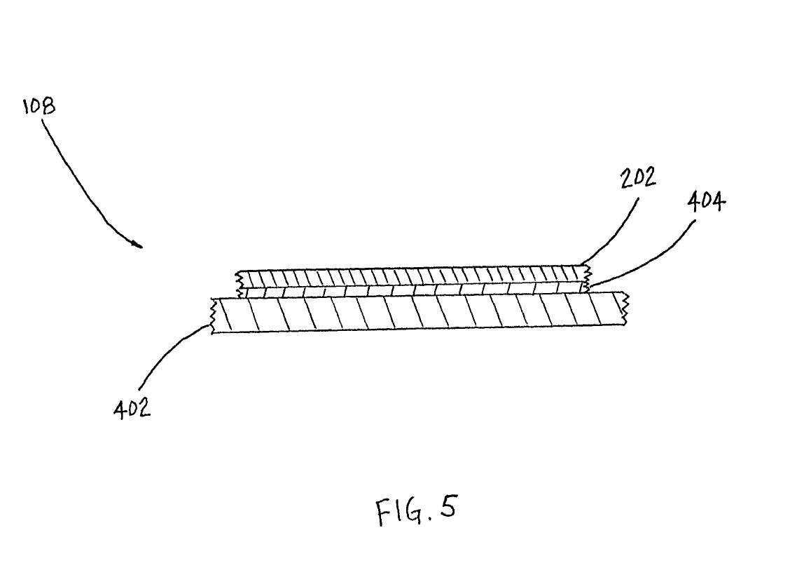

More specifically, FIG. 5 shows a cross-sectional view of the top-contact capacitor 108, taken along the line 5 of FIG. 4, that depicts the electrode 202 overlaying an oxide layer 404 formed on a substrate 402. The electrode 202 (and the electrode 204) may be formed using, e.g., a nickel-gold or an aluminum-copper composite, or preferably either aluminum or nickel; the oxide layer 404 may be formed using, e.g., silicon dioxide; and, the substrate 402 may be formed using, e.g., silicon.

Further, the capacitance of the top-contact capacitor 108 depends linearly on the dielectric constant of the oxide layer 404 and the areas of the electrodes 202 and 204, particularly, the lengths of contiguous adjacent edges (not numbered) of the electrodes 202 and 204. For example, desired lengths of the contiguous adjacent edges and desired areas of the electrodes 202 and 204 are obtained by interdigitating the electrodes 202 and 204, as shown in FIG. 4. The capacitance of the top-contact capacitor also depends inversely on the distance between the electrodes 202 and 204. Accordingly, a desired capacitance of the top-contact capacitor can be obtained by simply varying the lengths of the contiguous adjacent edges and the areas of the electrodes 202 and 204, and by varying the distance between the electrodes 202 and 204.

It should be understood that the substrate 102, the integrated circuit component 104, the RF coil antenna 106, and the top-contact capacitor 108 are conventional and therefore known to those skilled in this art. Accordingly, the specific structures used for implementing these components of the smart card assembly 100 are not critical to the present invention.

A flip-chip technique is used for interconnecting the top-contact capacitor 108 with both the RF coil antenna 106 and the integrated circuit component 104. A preferred flip-chip technique is described in U.S. Pat. No. 5,879,761 issued Mar. 9, 1999, and assigned to Polymer Flip Chip Corporation, Billerica, Mass., USA, which is fully incorporated herein by reference. Specifically, electrically conductive polymer bumps 206 and 208 are formed on bond pads 210 (see FIG. 2) of the integrated circuit component 104 and bond pads 111 (see also FIG. 1) of the conductive traces 110, which are points of interconnection with the electrodes 202 and 204 of the top-contact capacitor. The polymer bumps 206 and 208 are preferably formed by directing electrically conductive polymer through openings of a template (not shown) aligned with the locations of the bond pads 111 and 210 (see FIG. 2).

Next, surfaces of the top-contact capacitor 108, including surfaces of the electrodes 202 and 204, are coated with an organic protective layer (not shown). Locations on the electrodes 202 and 204 corresponding with the bond pads 111 and 210 are then exposed by laser ablation of the organic protective layer; and, the top-contact capacitor 108 is “flipped” for aligning and contacting the exposed locations with the polymer bumps 206 and 208 formed on the bond pads 111 and 210, respectively. FIG. 3 shows a side view of the smart card assembly 100 after the top-contact capacitor 108 has been flipped for alignment and contact with the polymer bumps 206 on the bond pads 111 of the conductive traces 110 and the polymer bumps 208 on the bond pads 210 of the integrated circuit component 104.

In this illustrative example, the area of the top-contact capacitor 108 is larger than the area of the integrated circuit component 104, thereby facilitating the alignment of the polymer bumps 206 and 208 with the electrodes 202 and 204. The electrically conductive polymer bumps 206 and 208 are then held in contact with the electrodes 202 and 204 of the top-contact capacitor, thereby forming an electrical circuit including the integrated circuit component 104, the RF coil antenna 106, and the top-contact capacitor 108.

As described above, the overall dimensions of the smart card assembly 100, including the substrate 102 and the protective outer layer, are preferably comparable to those of a conventional credit card. Accordingly, the thickness of the substrate 102 and the protective outer layer may typically be about 30 mils. This means that the thickness of the RF coil antenna 106 disposed on the substrate 102 may typically be about 15 mils; the thickness of the integrated circuit component 104 may typically be about 7 mils; the thickness of the top-contact capacitor 108 may be about 7 mils; and, the thickness of the polymer bumps 206 and 208 may be about 1 mil.

As known to those skilled in this art, the smart card assembly 100 is used as one part of a smart card system (not shown), which includes the non-contact smart card assembly 100 and a smart card reader/writer (not shown) for transmitting or receiving information, e.g., an ID number, between it and the non-contact smart card assembly 100 via radio waves. It is also known that radio waves generated by the smart card reader/writer may provide the energy that the non-contact smart card assembly 100 needs to operate.

Specifically, the conventional smart card reader/writer includes signal processing and control circuitry (not shown), which provides information to be transmitted to a modulator (not shown), e.g., a frequency shift keying (FSK) modulator. The smart card reader/writer also conventionally includes filtering and amplification circuitry (not shown), which filters and amplifies modulated signals from the FSK modulator and provides the signals to a coil antenna (not shown) of the smart card reader/writer for transmitting or “writing” the signal information to the smart card assembly 100.

The resonance circuit of the smart card assembly 100, including the top-contact capacitor 108 connected in parallel with the RF coil antenna 106, then receives or “reads” the signal information provided by the first coil antenna of the smart card reader/writer. Because the top-contact capacitor 108 is also connected across the bond pads 210 of the integrated circuit component 104, the signal information is provided to filtering circuitry (not shown) and a FSK demodulator (not shown) included in the integrated circuit component 104. Signal processing and control circuitry (not shown) of the integrated circuit component 104 are then used to store the demodulated information in a memory (not shown) included in the integrated circuit component 104.

In addition, the signal processing and control circuitry of the integrated circuit component 104 may read information, e.g., the ID number, from the memory and provide it to a modulator (not shown), e.g., an amplitude shift keying (ASK) modulator, included in the integrated circuit component 104. The modulated signal information may then be amplified by amplification circuitry (not shown) of the integrated circuit component 104, and provided to the resonance circuit (i.e., the top-contact capacitor 108 and the RF coil antenna 106) for transmission to the smart card reader/writer.

Next, the coil antenna of the smart card reader/writer receives or “reads” the signal information provided by the RF coil antenna 106 of the smart card assembly 100. The received signal information is then provided to filtering circuitry (not shown) and an ASK demodulator (not shown) included in the smart card reader/writer. The signal processing and control circuitry of the smart card reader/writer are then used, e.g., to either store the demodulated information in a memory (not shown) included in the smart card reader/writer or execute a predetermined control sequence in accordance with the demodulated information.

For example, in a typical application, the smart card assembly 100 may be used as a RF-ID tag. Specifically, the smart card system may be used for controlling access to a secured facility. Accordingly, the smart card reader/writer may “read” an ID number provided by the smart card assembly 100, and then either allow or prohibit access to the secured facility depending upon the received information. This may be done by controlling a lock on a door or the like. Other applications of the RF-ID tag are also possible.

It follows from the above description that important advantages are derived from the smart card assembly of the present invention. For example, the smart card assembly is less expensive to manufacture. This is because flip-chip bonding techniques are used for interconnecting the top-contact capacitor 108 with both the integrated circuit component 104 and the conductive leads 110 of the RF coil antenna 106. As a result, automated equipment may be used for depositing the polymer bumps 206 and 208 on the bond pads 111 of the conductive leads 110 and the bond pads 210 of the integrated circuit component 104 and then flipping the top-contact capacitor 108 for interconnecting the polymer bumps 206 and 208 with the electrodes 202 and 204 of the top-contact capacitor. In contrast, wire bonding techniques that are conventionally used for interconnecting a resonance circuit with other components of a smart card typically require some manual assembly and therefore result in more expensive smart card assemblies.

Further, because the smart card assembly can be manufactured by automated equipment, the smart card assembly of the present invention is expected to have higher reliability as compared with smart cards manufactured using the conventional techniques.

Having described one embodiment, numerous alternative embodiments or variations can be made by those skilled in the art. For example, it was described that a flip-chip technique is used for interconnecting the top-contact capacitor 108 with both the RF coil antenna 106 and the integrated circuit component 104. In an alternative embodiment, the integrated circuit component 104 can be an integrated circuit die attached to a lead frame (not shown) and then encapsulated in a suitable polymeric body (not shown). The top-contact capacitor 108 may then be suitably interconnected with the integrated circuit component 104 using the lead frame.

In addition, it was described that interconnections between the top-contact capacitor 108 and the integrated circuit component 104 and the conductive traces 110 of the RF coil antenna 106 are formed using the polymer bumps 206 and 208 deposited on the bond pads 111 and 210. However, this was merely an illustrative example. The polymer bumps 206 and 208 alternatively can be deposited at suitable locations on the electrodes 202 and 204 of the top-contact capacitor. Further, the substrate 102, the integrated circuit component 104, and the RF coil antenna 106 can be coated with the organic protective layer; and, the bond pads 111 and 210 can be exposed by laser ablation of the organic protective layer. The top-contact capacitor 108 then can be flipped for contacting the polymer bumps 206 and 208 with the bond pads 111 and 210 of the conductive traces 110 and the integrated circuit component 104, respectively.

Further, the bumps 206 and 208 can be formed using other materials. For example, the bumps 206 and 208 can be formed by plating layers of metal on the bond pads 111 and 210. The substrate 102 including the integrated circuit component 104 and the RF coil antenna 106 then can be heated to reflow the layers of metal. Next, the top-contact capacitor 108 can be flipped for aligning the electrodes 202 and 204 with the metal bumps on the bond pads 111 and 210 of the conductive traces 110 and the integrated circuit component, respectively. Finally, the smart card assembly 100 including the substrate 102, the integrated circuit component 104, the RF coil antenna 106, and the top-contact capacitor 108 can be heated again to form the interconnections. Alternatively, the bumps 206 and 208 can be formed by plating the layers of metal at suitable locations on the electrodes 202 and 204.

It was also described that the area of the top-contact capacitor 108 is larger than the area of the integrated circuit component 104. However, this was also merely an illustrative example. The area of the top-contact capacitor 108 alternatively can be the same as or smaller than that of the integrated circuit component 104, so long as a desired capacitance of the top-contact capacitor can be obtained and the top-contact capacitor can be easily interconnected with the integrated circuit component 104 and the RF coil antenna 106 using automated equipment.

Also, a specific example of a top-contact capacitor 108 was described and depicted. However, this was merely by way of illustration. Alternative implementations of the capacitor can be used, so long as interconnections between electrodes of the capacitor and other components of the smart card assembly 100 can be formed using flip-chip techniques.

Also, a specific example of a smart card system incorporating the smart card assembly 100 was described. However, this was also merely by way of illustration. Alternative implementations of the smart card system using alternative RF modulation/demodulation and transmission techniques can be used.

The present invention has been described in detail including the preferred embodiments thereof. However, it should be appreciated that those skilled in this art, upon consideration of the present disclosure, may make modifications and/or improvements on this invention and still be within the scope and the spirit of this invention as set forth in the following claims.

What is claimed is:

1. A smart card assembly, comprising:
a substrate having a face;
a resonance circuit including
a RF antenna formed on the face of the substrate for transmitting or receiving RF signals, and
a thin film capacitor operatively coupled to the RF antenna; and
an integrated circuit component mounted to the face of the substrate, the integrated circuit component comprising bond pads and being operatively coupled to the capacitor of the resonance circuit, for processing the RF signals,
wherein the capacitor is coupled electrically to terminals of the RF antenna and bond pads of the integrated circuit component by pressure contact.

2. The smart card assembly as recited in claim 1,
wherein the capacitor is a top-contact capacitor.

3. The smart card assembly as recited in claim 1,
wherein the substrate defines a component cavity at the face and the integrated circuit component is mounted to the substrate within the cavity.

4. The smart card assembly as recited in claim 3,
wherein the capacitor is in an overlaying relationship relative to the integrated circuit component in the cavity.

5. A method of manufacturing a smart card assembly comprising a substrate having a face; a resonance circuit including a RF antenna formed on the face of the substrate for transmitting or receiving RF signals, and a thin film capacitor operatively coupled to the RF antenna; and an integrated circuit component mounted to the face of the substrate, the integrated circuit component comprising bond pads and being operatively coupled to the capacitor of the resonance circuit, for processing the RF signals, wherein the capacitor is coupled electrically to terminals of the RF antenna and bond pads of the integrated circuit component by pressure contact, the method including the steps of:
(a) forming electrically conductive bumps on the bond pads of the integrated circuit component and the terminals of the RF antenna;
(b) aligning electrodes of the capacitor with the bumps formed on the bond pads of the integrated circuit component and the terminals of the RF antenna; and
(c) contacting the electrodes of the capacitor with the electrically conductive bumps.

6. The method as recited in claim 5,
wherein the electrically conductive bumps are polymer bumps.

7. The method as recited in claim 5,
wherein the forming of step (a) includes the substeps of
aligning openings of a template with the bond pads of the integrated circuit component and the terminals of the RF antenna, and
directing electrically conductive polymer through the openings of the template.

8. The method as recited in claim 5,
further including the steps of
coating a face of the capacitor with an organic protective layer, and
exposing contact locations on the electrodes using laser ablation.

9. A method of manufacturing a smart card assembly comprising a substrate having a face; a resonance circuit including a RF antenna formed on the face of the substrate for transmitting or receiving RF signals, and a thin film capacitor operatively coupled to the RF antenna; and an integrated circuit component mounted to the face of the substrate, the integrated circuit component comprising bond pads and being operatively coupled to the capacitor of the resonance circuit, for processing the RF signals, wherein the capacitor is coupled electrically to terminals of the RF antenna and bond pads of the integrated circuit component by pressure contact, the method including the steps of:
(a) forming electrically conductive bumps on electrodes of the capacitor;
(b) aligning the bond pads of the integrated circuit component and the terminals of the RF antenna with the bumps formed on the electrodes; and
(c) contacting the bond pads and the terminals with the bumps formed on the electrodes.

10. The method as recited in claim 9,
wherein the electrically conductive bumps are polymer bumps.

11. The method as recited in claim 9,
wherein the forming of step (a) includes the substeps of
aligning openings of a template with contact locations on the electrodes of the capacitor, and
directing electrically conductive polymer through the openings of the template.

12. The method as recited in claim 9,
further including the steps of
coating the face of the substrate including the integrated circuit component and the RF antenna mounted thereto with an organic protective layer, and
exposing the bond pads of the integrated circuit component and the terminals of the RF antenna using laser ablation.
